(19) United States
(12) Patent Application Publication
(10) Pub. No.: US 2025/0151195 A1
(43) Pub. Date: May 8, 2025

(54) WIRING SUBSTRATE

(71) Applicant: IBIDEN CO., LTD., Ogaki (JP)

(72) Inventor: Masashi KUWABARA, Ibi-gun (JP)

(73) Assignee: IBIDEN CO., LTD., Ogaki (JP)

(21) Appl. No.: 18/897,602

(22) Filed: Sep. 26, 2024

(30) Foreign Application Priority Data
Sep. 28, 2023 (JP) 2023-168571

(51) Int. Cl. H05K 1/11; H05K 1/03; H05K 1/18; H05K 3/40; H05K 3/46

(52) U.S. Cl. CPC H05K 1/113; H05K 1/0306; H05K 1/181; H05K 3/4076; H05K 3/4644; H05K 2201/09409; H05K 2201/096; H05K 2201/09636; H05K 2203/072; H05K 2203/083

(57) ABSTRACT

A wiring substrate includes a first build-up part including a first conductor layer, a first insulating layer, and first via conductors penetrating through the first insulating layer, a second build-up part including second conductor layers, second insulating layers, and second via conductors penetrating though the second insulating layers, a third build-up part including a third conductor layer, a third insulating layer, and third via conductors penetrating through the third insulating layers such that the second built-up part is formed between the first built-up part and the third build-up part. The first, second and third build-up parts are formed such that a diameter of each of the first via conductors is smaller than a diameter of each of the second via conductors and that the diameter of each of the second via conductors is smaller than a diameter of each of the third via conductors.

### CROSS-REFERENCE TO RELATED APPLICATIONS

The present application is based upon and claims the benefit of priority to Japanese Patent Application No. 2023-168571, filed Sep. 28, 2023, the entire contents of which are incorporated herein by reference.

### BACKGROUND OF THE INVENTION

### Field of the Invention

The present invention relates to a wiring substrate.

### Description of Background Art

International Publication No. 2010/010910 describes a coreless substrate. The entire contents of this publication are incorporated herein by reference.

### SUMMARY OF THE INVENTION

According to one aspect of the present invention, a wiring substrate includes a first build-up part including a first conductor layer, a first insulating layer, and first via conductors penetrating through the first insulating layer, a second build-up part including second conductor layers, second insulating layers, and second via conductors penetrating though the second insulating layers, a third build-up part including a third conductor layer, a third insulating layer, and third via conductors penetrating through the third insulating layer such that the second built-up part is formed between the first built-up part and the third build-up part. The first, second and third build-up parts are formed such that a diameter of each of the first via conductors is smaller than a diameter of each of the second via conductors and that the diameter of each of the second via conductors is smaller than a diameter of each of the third via conductors.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2A illustrates an example of a method for manufacturing a wiring substrate according to an embodiment of the present invention;

FIG. 2B illustrates an example of a method for manufacturing a wiring substrate according to an embodiment of the present invention;

FIG. 2C illustrates an example of a method for manufacturing a wiring substrate according to an embodiment of the present invention;

FIG. 2D illustrates an example of a method for manufacturing a wiring substrate according to an embodiment of the present invention;

FIG. 2E illustrates an example of a method for manufacturing a wiring substrate according to an embodiment of the present invention;

FIG. 2F illustrates an example of a method for manufacturing a wiring substrate according to an embodiment of the present invention;

FIG. 2G illustrates an example of a method for manufacturing a wiring substrate according to an embodiment of the present invention;

FIG. 2H illustrates an example of a method for manufacturing a wiring substrate according to an embodiment of the present invention;

FIG. 2I illustrates an example of a method for manufacturing a wiring substrate according to an embodiment of the present invention;

FIG. 2J illustrates an example of a method for manufacturing a wiring substrate according to an embodiment of the present invention;

FIG. 2K illustrates an example of a method for manufacturing a wiring substrate according to an embodiment of the present invention;

FIG. 2L illustrates an example of a method for manufacturing a wiring substrate according to an embodiment of the present invention; and

FIG. 2M illustrates an example of a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

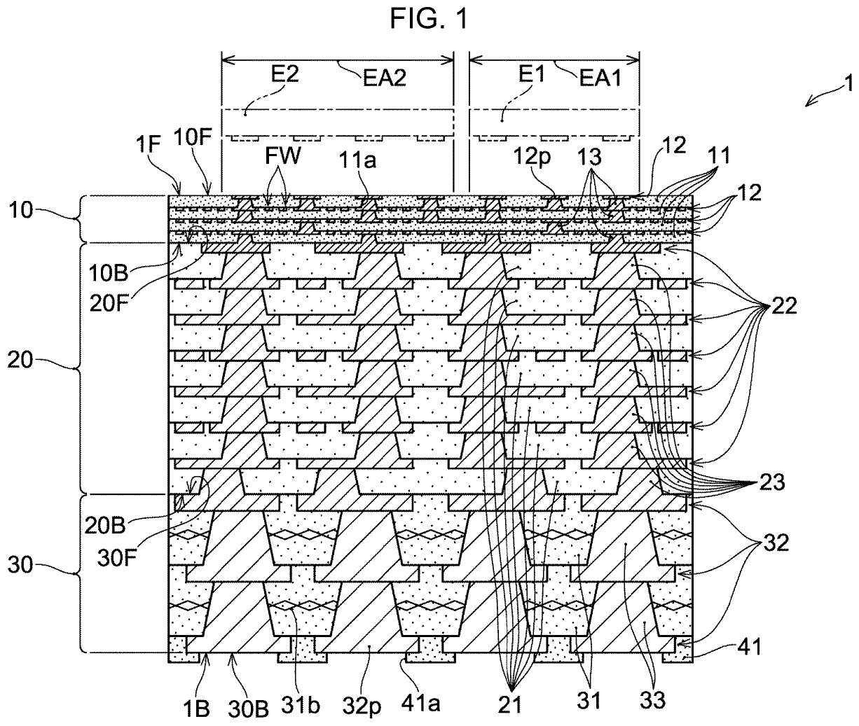

A wiring substrate according to an embodiment of the present invention is described with reference to the drawings. FIG. 1 is a cross-sectional view illustrating a wiring substrate 1 according to an embodiment of the present invention. A laminated structure, and the number of conductor layers and the number of insulating layers, of a wiring substrate are not limited to the laminated structure of the wiring substrate 1 of FIG. 1, and the number of conductor layers and the number of insulating layers included in the wiring substrate 1.

The wiring substrate 1 of the embodiment has a laminated structure that includes a first build-up part 10, a second build-up part 20, and a third build-up part 30, which are each formed of alternately laminated multiple conductor layers and multiple insulating layers. The wiring substrate 1 has two surfaces (a first surface (1F) and a second surface (1B) on the opposite side with respect to the first surface (1F)) orthogonal to a thickness direction thereof.

The first build-up part 10 has a surface (10F) on one side and a surface (10B) on the other side, the opposite side with respect to the surface (10F). The second build-up part 20 has a surface (20F) on one side and a surface (20B) on the other side, the opposite side with respect to the surface (20F). The third build-up part 30 has a surface (30F) on one side and a surface (30B) on the other side, the opposite side with respect to the surface (30F). As illustrated in FIG. 1, the surface (10F) of the first build-up part 10 forms the first surface (1F). The second surface (1B) is formed by the surface (30B) of the third build-up part 30.

In the illustrated example, the second build-up part 20 is formed below the first build-up part 10, with the surface (20F) of the second build-up part 20 facing the surface (10B) of the first build-up part 10. The third build-up part 30 is formed below the second build-up part 20, with the surface (30F) of the third build-up part 30 facing the surface (20B) of the second build-up part 20.

In the description of the wiring substrate 1 of the present embodiment illustrated in FIG. 1, the one surface (10F) side of the first build-up part 10, that is, the first surface (1F) side of the wiring substrate 1 is referred to as “upper” or an “upper side,” and the second surface (1B) side of the wiring substrate 1 is referred to as “lower” or a “lower side.” Further, for each of the structural elements, a surface facing the first surface (1F) side of the wiring substrate 1 is also referred to as an “upper surface,” and a surface facing the second surface (1B) side of the wiring substrate 1 is also referred to as a “lower surface.”

In the illustrated example, the first build-up part 10, the second build-up part 20, and the third build-up part 30 each include multiple insulating layers and multiple conductor layers. In the wiring substrate of the embodiment, at least the second build-up part 20 includes multiple insulating layers and multiple conductor layers. Specifically, in the illustrated example, the first build-up part 10 includes four first insulating layers 11 and four first conductor layers 12, the second build-up part 20 includes seven second insulating layers 21 and seven second conductor layers 22, and the third build-up part 30 includes two third insulating layers 31 and three third conductor layers 32. That is, an example is illustrated in which the number of the second insulating layers 21 is greater than the number of the first insulating layers 11, and the number of the second conductor layers 22 is greater than the number of the first conductor layers 12.

As illustrated in the drawing, the first build-up part 10 includes alternately laminated insulating layers (first insulating layers) 11 and conductor layers (first conductor layers) 12. Opposing conductor layers (either conductor layers 12, or a conductor layer 12 and a conductor layer 22) that face each other with one insulating layer 11 in between are connected by via conductors (first via conductors) 13. The second build-up part 20 includes alternately laminated insulating layers (second insulating layers) 21 and conductor layers (second conductor layers) 22. Opposing conductor layers (either conductor layers 22, or a conductor layer 22 and a conductor layer 32) that face each other with one insulating layer 21 in between are connected by via conductors (second via conductors) 23. The third build-up part 30 includes alternately laminated insulating layers (third insulating layers) 31 and conductor layers (third conductor layers) 32. Opposing conductor layers (either conductor layers 32, or a conductor layer 22 and a conductor layer 32) that face each other with one insulating layer 31 in between are connected by via conductors (third via conductors) 33.

The first via conductors 13 included in the first build-up part 10, the second via conductors 23 included in the second build-up part 20, and the third via conductors 33 included in the third build-up part 30 have different dimensions. Specifically, a diameter of each of the first via conductors 13, a diameter of each of the second via conductors 23, and a diameter of each of the third via conductors 33 are different. The diameter of each of the first via conductors 13 is smaller than the diameter of each of the second via conductors 23, and the diameter of each of the second via conductors 23 is smaller than the diameter of each of the third via conductors 33. The term “diameter” in the description of the via conductors (13, 23, 33) means a distance between two farthest points on an outer perimeter in a cross section along a horizontal direction (extension direction of the insulating layers (11, 21, 31)). The via conductors (13, 23, 33) are not necessarily limited to each having a circular horizontal cross-sectional shape, but can each have any shape, such as a circular, elliptical, or rectangular shape, in a plan view.

In particular, regarding the diameters of the via conductors (13, 23, 33), the phrase “the diameter of each of the first via conductors 13 is smaller than the diameter of each of the second via conductors 23” means that a maximum diameter of each of the first via conductors 13 at an upper surface of a lower conductor layer (a conductor layer 12 or a conductor layer 22) to which the first via conductors 13 are connected in the first build-up part 10 is smaller than a minimum diameter of each of the second via conductors 23 at an upper surface of a lower conductor layer (a conductor layer 22 or a conductor layer 32) to which the second via conductors 23 are connected in the second build-up part 20. Further, the phrase “the diameter of each of the second via conductors 23 is smaller than the diameter of each of the third via conductors 33” means that a maximum diameter of each of the second via conductors 23 at an upper surface of a lower conductor layer (a conductor layer 22 or a conductor layer 32) to which the each of the second via conductors 23 is connected in the second build-up part 20 is smaller than a maximum diameter of each of the third via conductors 33 at an upper surface of a lower conductor layer 32 to which the each of the third via conductors 33 is connected in the third build-up part 30.

As described above, the wiring substrate of the embodiment includes multiple build-up parts (the first build-up part 10, the second build-up part 20, and the third build-up part 30) that respectively include the via conductors of different diameters, and further, at least the second build-up part 20 includes multiple insulating layers 21 and multiple conductor layers 22. In the wiring substrate of the embodiment, by providing the multiple build-up parts that respectively include the via conductors of different diameters, it is possible to form a wiring circuit that passes through the via conductors and has a relatively stable characteristic impedance in each of the build-up parts. Further, by including multiple insulating layers and multiple conductor layers in at least one of the build-up parts, it may be possible that a more complex wiring circuit can be formed in each of the build-up parts. For example, in a build-up part that includes multiple insulating layers and multiple conductor layers, it may be possible to form a wring with a stripline structure. The diameter of each of the first via conductors 13 at the upper surface of the lower conductor layer to which the each of the first via conductors 13 is connected is about 10 μm. The diameter of each of the second via conductors 23 at the upper surface of the lower conductor layer to which the each of the second via conductors 23 is connected is about 50 μm. The diameter of each of the third via conductors 33 at the upper surface of the lower conductor layer to which the each of the third via conductors 33 is connected is about 100 μm.

The surface (10F) of the first build-up part 10 is formed by upper surfaces of the uppermost first insulating layer 11 and conductor layer 12 in the first build-up part 10. The surface (10B) of the first build-up part 10 is formed by a lower surface of the lowermost insulating layer 11 in the first build-up part 10. The surface (20F) of the second build-up part 20 is formed by upper surfaces of the uppermost second insulating layer 21 and conductor layer 22 in the second build-up part 20. The surface (20B) of the second build-up part 20 is formed by a lower surface of the lowermost insulating layer 21 in the second build-up part 20. The surface (30F) of the third build-up part 30 is formed by upper surfaces of the uppermost third insulating layer 31 and conductor layer 32 in the third build-up part 30. The surface (30B) of the third build-up part 30 is formed by a lower surface of the lowermost insulating layer 31 in the third build-up part 30.

The conductor layer 22 that forms the surface (20F) of the second build-up part 20 and the via conductors 13 that are formed in the lowermost insulating layer 11 of the first build-up part 10 are integrally formed. In the integrally formed via conductors 13 and conductor layer 22, a level corresponding to the lower surface of the insulating layer 11 that forms the surface (10B) of the first build-up part 10 is regarded as a boundary between the first build-up part 10 and the second build-up part 20. That is, a level corresponding to the lower surface of the insulating layer 11 that forms the surface (10B) of the first build-up part 10 (a level corresponding to the upper surface of the conductor layer 22 that forms the surface (20F) of the second build-up part 20) corresponds to a boundary between the via conductors 13 and the conductor layer 22. Further, the conductor layer 32 that forms the surface (30F) of the third build-up part 30 and the via conductors 23 that are formed in the lowermost insulating layer 21 of the second build-up part 20 are integrally formed. In the integrally formed via conductors 23 and conductor layer 32, a level corresponding to the lower surface of the insulating layer 21 that forms the surface (20B) of the second build-up part 20 (a level corresponding to the upper surface of the conductor layer 32 that forms the surface (30F) of the third build-up part 30) is regarded as a boundary between the second build-up part 20 and the third build-up part 30.

The conductor layers 12 are each patterned to have predetermined conductor patterns. The first conductor layers 12 in the first build-up part 10 can include relatively fine wirings (first wirings) (FW) and can have relatively dense circuit wirings. In the illustrated example, the first conductor layer 12 that forms the surface (10F) is formed to have patterns including multiple conductor pads (12p). The conductor pads (12p) form a component mounting surface of the wiring substrate 1, which is an outermost surface of the wiring substrate 1 and to which an external electronic component can be connected. The component mounting surface of the wiring substrate 1 can have multiple component mounting regions. For example, as illustrated in the example of FIG. 1, two component mounting regions (EA1, EA2) can be formed corresponding to regions where electronic components (E1, E2) are to be mounted.

In mounting external electronic components to the wiring substrate 1 in the illustrated example, upper surfaces of the conductor pads (12p) can be electrically and mechanically connected to the external electronic components, for example, via a conductive bonding material such as solder (not illustrated in the drawings) interposed between the conductor pads (12p) and connection pads of the external electronic components. In this case, for example, a plating layer (not illustrated in the drawings) including a nickel layer and a tin layer may be formed in advance on the upper surfaces of the conductor pads (12p).

When the multiple component mounting regions are formed, conductor patterns can be formed in the conductor layers 12 in the first build-up part 10 such that conductor pads (12p) positioned in different component mounting regions can be electrically connected to each other. In using the wiring substrate 1, multiple electronic components to be mounted can be electrically connected to each other via the conductor layers 12 in the first build-up part 10 in short paths. Further, as a result, in using the wiring substrate 1, it may be possible to improve flexibility in designing circuits via multiple electronic components that can be mounted.

Examples of the electronic components (E1, E2) that can be mounted on the wiring substrate 1 include electronic components such as active components such as semiconductor integrated circuit devices and transistors. Specifically, for example, the electronic components can each be an integrated circuit such as a logic chip incorporating a logic circuit, a processing unit such as an MPU (Micro Processor Unit), or a memory element such as an HBM (High Bandwidth Memory).

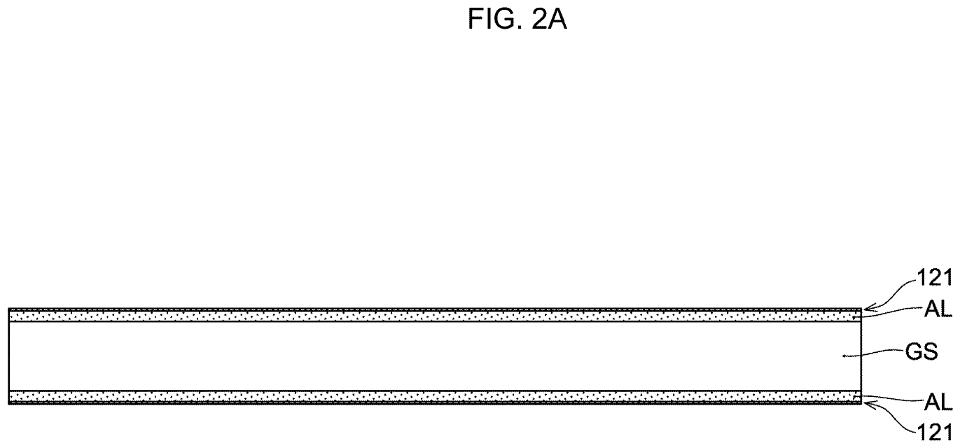

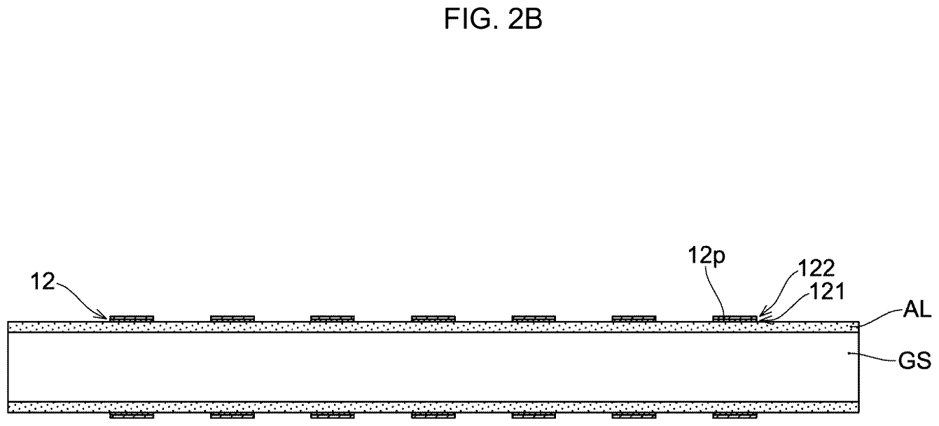

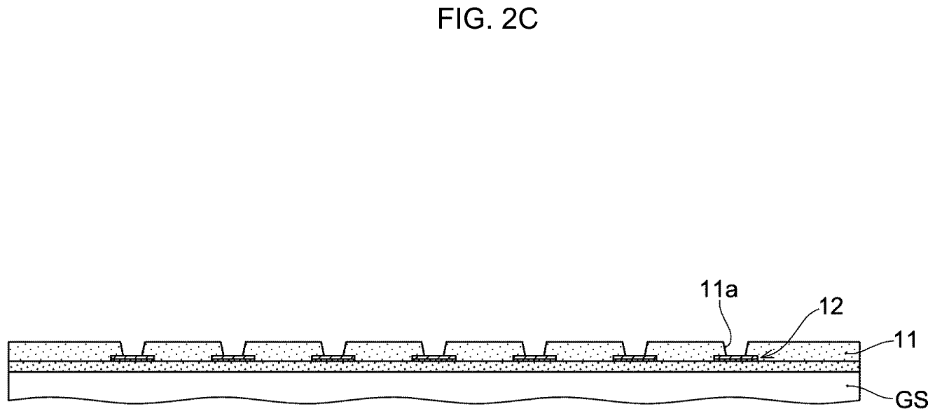

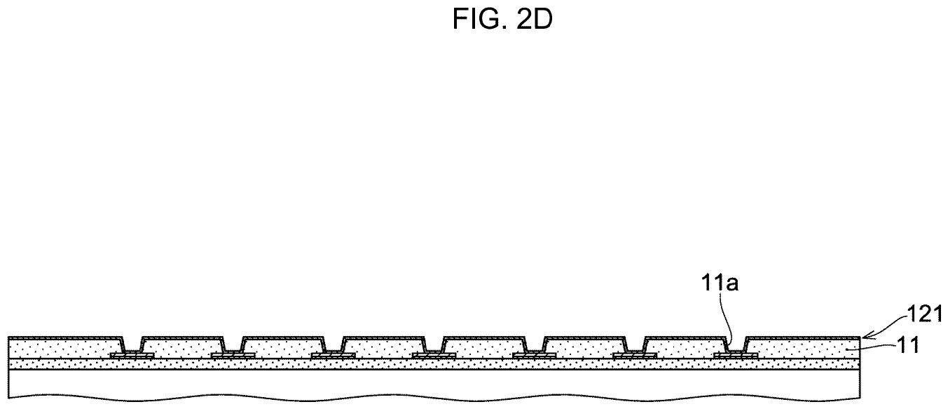

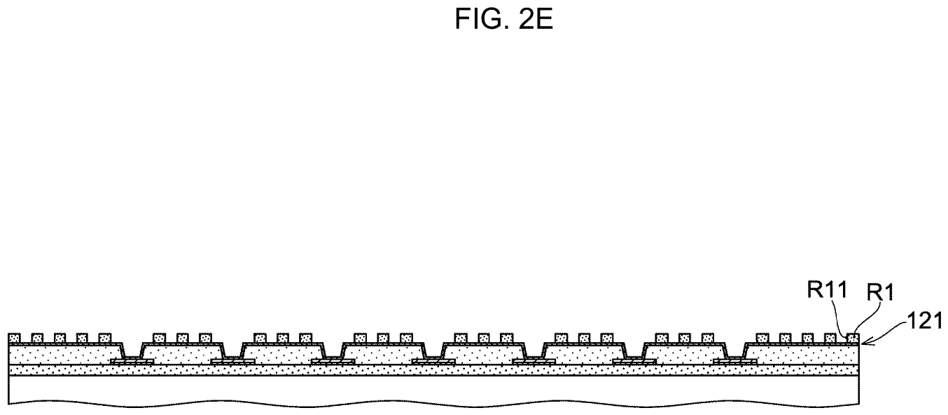

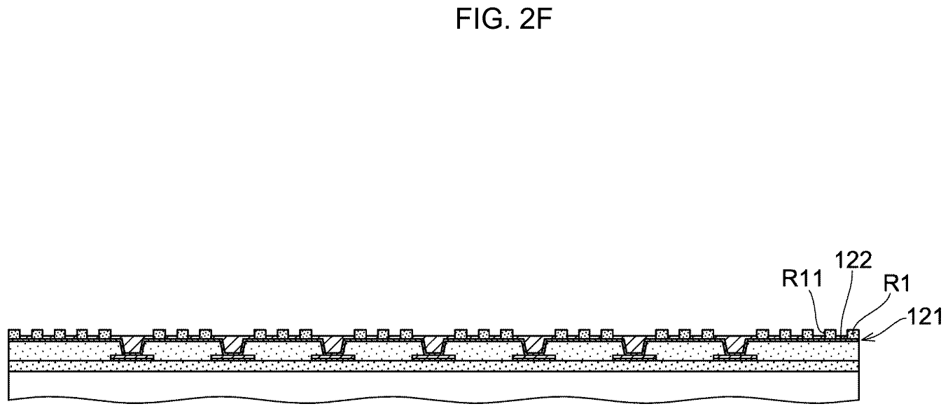

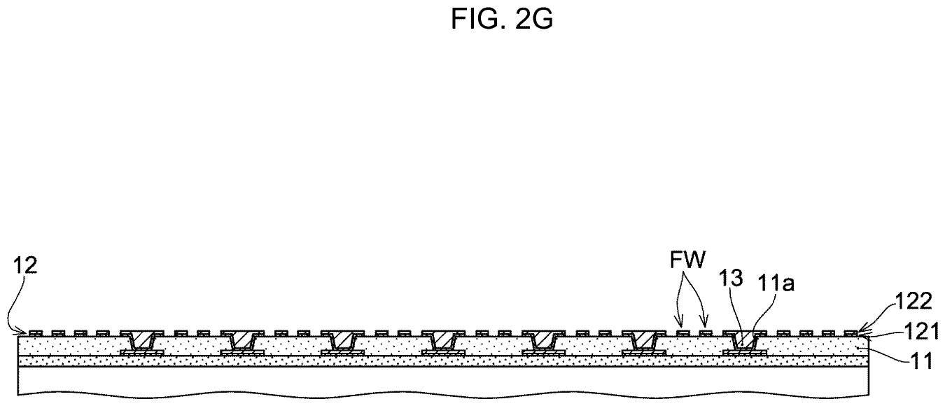

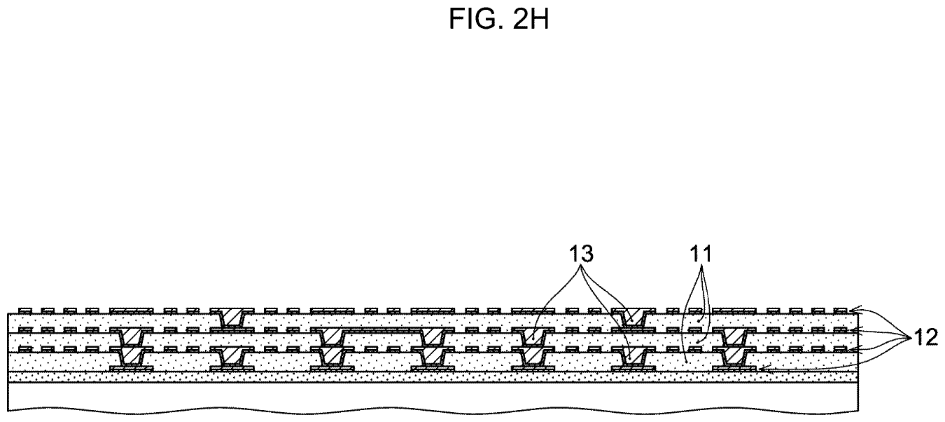

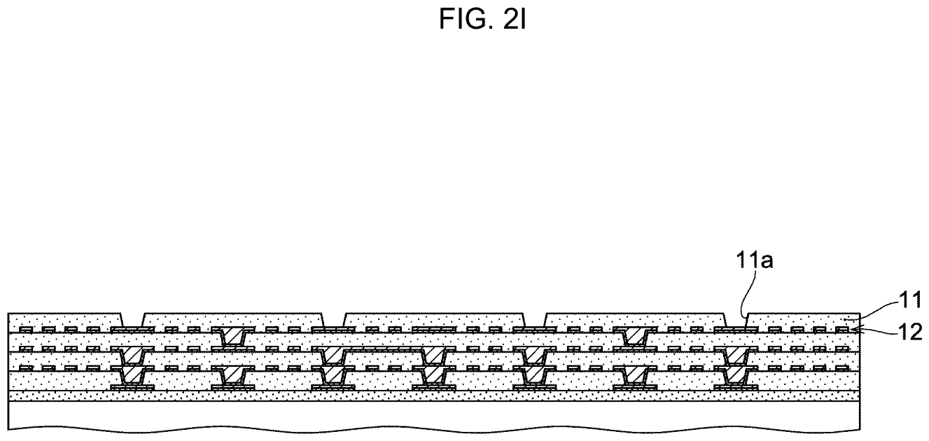

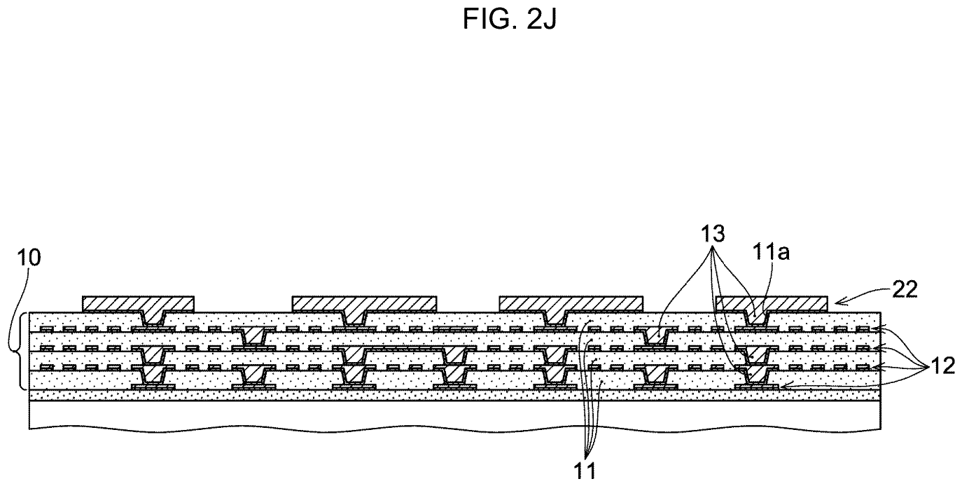

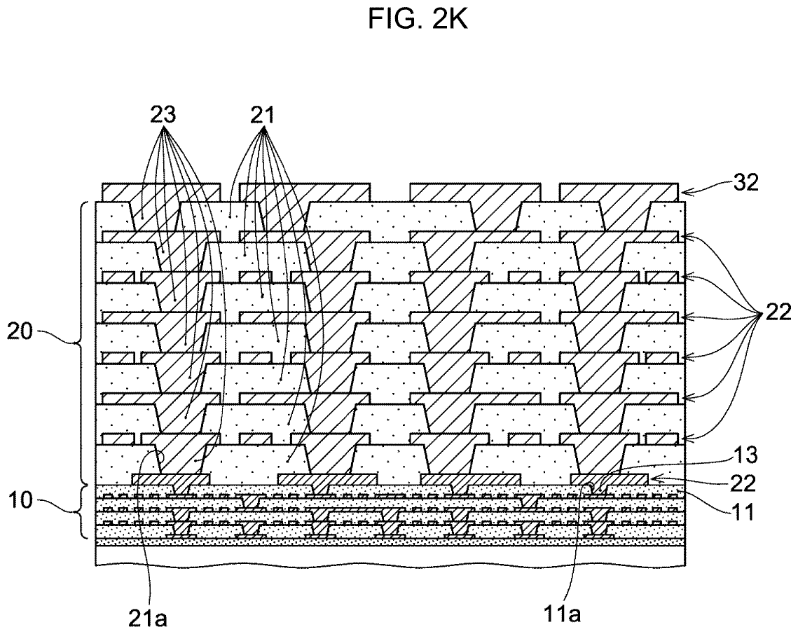

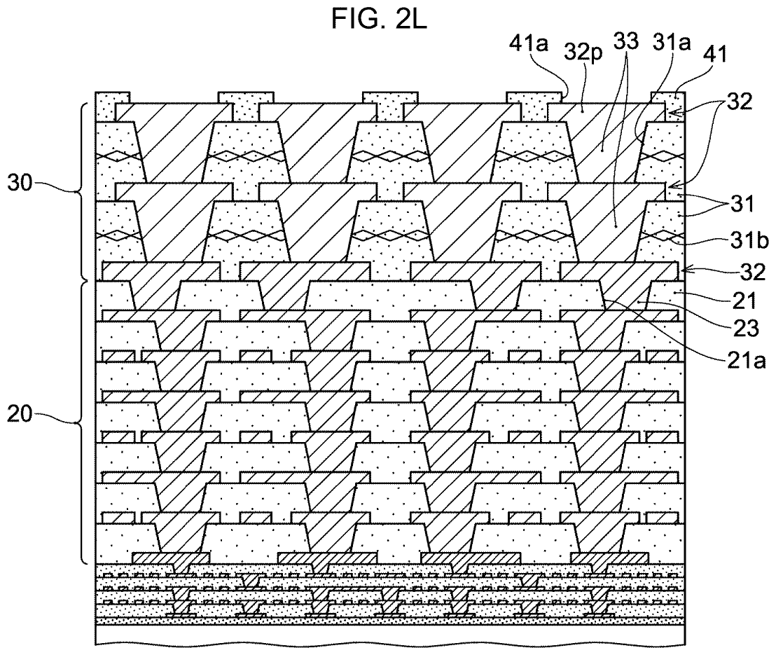

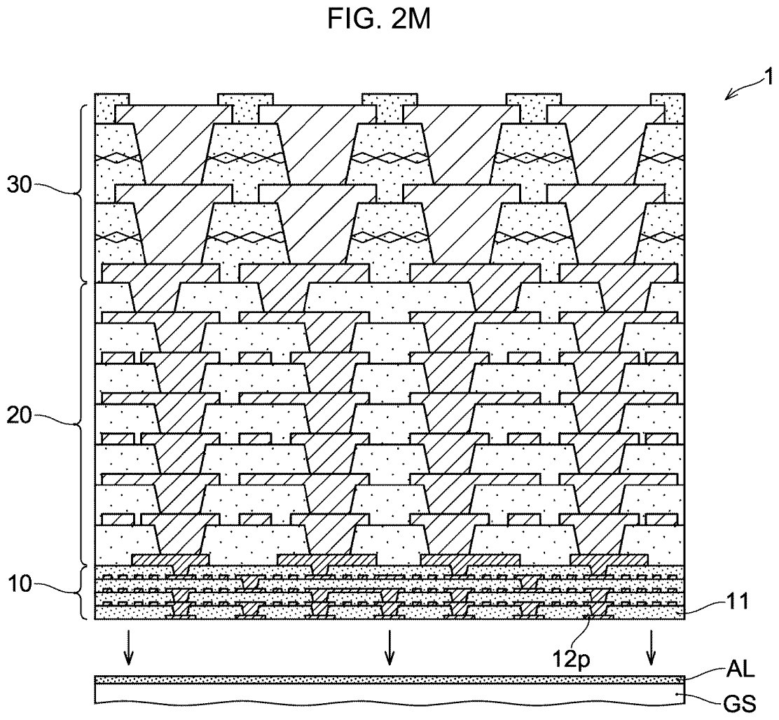

The first insulating layers 11 of the first build-up part 10 can be formed, for example, using an insulating resin such as an epoxy resin or a phenol resin. The insulating layers 11 may contain one of a fluorine resin, a liquid crystal polymer (LCP), a fluoroethylene resin (PTFE), a polyester resin (PE), and a modified polyimide resin (MPI). Examples of a conductor forming the conductor layers 12 and the via conductors 13 include copper, nickel, and the like, and copper is preferably used. In the example illustrated in FIG. 1, the conductor layers 12 and the via conductors 13 are each illustrated as having a single-layer structure. However, the conductor layers 12 and the via conductors 13 may each have a multilayer structure. For example, the conductor layers 12 and the via conductors 13 can each have a two-layer structure including a metal film layer 121 (see FIG. 2G), which can be, for example, a sputtering film layer or an electroless plating film layer, and a plating film layer 122 (see FIG. 2G), which can be, for example, an electrolytic plating film layer.

The via conductors 13 connecting conductor layers 12 facing each other with an insulating layer 11 in between are formed by filling through holes (11a) penetrating the insulating layer 11 with conductors. In the example of FIG. 1, each via conductor 13 is integrally formed with a conductor layer 12 provided on a lower side thereof. The illustrated via conductors 13 formed in the lowermost insulating layer 11 are integrally formed with the conductor layer 22.

The through holes (11a) for forming the via conductors 13 can be formed at the positions in the insulating layers 11 where the via conductors 13 are to be formed, for example, by irradiating laser from the lower surface side of each of the insulating layers 11. A diameter of each of the through holes (11a) is larger on a laser irradiation side and becomes smaller on the opposite side (deep side) with respect to the laser irradiation side. Therefore, the through holes (11a) can be formed to each have a larger diameter on a lower side and a smaller diameter on an upper side. As illustrated in FIG. 1, the via conductors 13 included in the first build-up part 10 are formed to each have a tapered shape that is reduced in diameter from the second surface (10B) toward the first surface (10F) of the first build-up part 10. The term “reduced in diameter” simply means that a distance between two farthest points on an outer perimeter of a horizontal cross section of each of the via conductors 13 is reduced. For example, the through holes (11a) can be formed such that an aspect ratio of each via conductor 13 ((shortest distance from the upper surface of the lower conductor layer to the lower surface of the upper conductor layer, the lower and upper conductor layers being connected by the via conductor 13)/(diameter of the via conductor 13 at the upper surface of the lower conductor layer)) is about 0.5 or more and about 1.0 or less.

The conductor layers 12 of the wiring substrate 1 can have wirings (first wirings) (FW) that are high-density wirings with relatively small pattern widths and inter-pattern distances. The wirings (FW) can have smallest pattern widths and inter-pattern distances among wirings of the wiring substrate 1. In the illustrated example, among the multiple conductor layers 12 included in the first build-up part 10, three conductor layers 12 have the wirings (FW), which are high-density wirings. However, the number of the conductor layers 12 having the wirings (FW) in the first build-up part 10 is not limited.

The wirings (first wirings) (FW) included in the first build-up part 10 can have pattern widths smaller than a minimum pattern width of wirings included in the conductor layers 22 (second conductor layers 22) in the second build-up part 20 and the conductor layers 32 (third conductor layers 32) in the third build-up part 30. Further, the wirings (first wirings) (FW) included in the first build-up part 10 can have inter-pattern distances smaller than a minimum inter-pattern distance of the wirings included in the conductor layers 22 (second conductor layers 22) in the second build-up part 20 and the conductor layers 32 (third conductor layers 32) in the third build-up part 30. Specifically, for example, the wirings (FW) have wiring widths of 3 μm or less and inter-wiring distances of 3 μm or less. Since the first build-up part 10 has the relatively fine wirings (FW), it may be possible to provide wirings with more appropriate characteristics corresponding to electrical signals that can be transmitted via the wirings in the first build-up part 10. From the same point of view, an aspect ratio of each of the conductor layers 12 having the wirings (FW) can be, for example, 2.0 or more and 4.0 or less. The above-described conductor patterns that electrically connect the conductor pads (12p) positioned in different component mounting regions can be formed by the wirings (FW).

When the conductor layers 12 are formed to include the wirings (FW) formed with fine pitches and aspect ratios as described above, it may be preferable that the via conductors 13 are also formed with fine pitches. The through holes (11a) for the via conductors 13 are formed with small diameters in the insulating layers 11. Therefore, although the insulating layers 11 can contain an inorganic filler such as fine particles of silica (SiO₂), alumina, mullite, or the like, it may be preferred that the insulating layers 11 do not contain an inorganic filler in order to facilitate the formation of the through holes (11a) with small diameters.

In the first build-up part 10 including the conductor layers 12 including the wirings (FW), the insulating layers 11 each have a thickness of, for example, about 7-10 μm. Further, in this case, the insulating layers 11 preferably do not each contain a core material (reinforcing material) formed of a glass fiber, an aramid fiber, or the like. The conductor layers 12 each have a thickness of, for example, 7 μm or less.

The insulating layers 21 of the second build-up part 20 and the insulating layers 31 of the third build-up part 30 can be formed using an insulating resin similar to that used for the insulating layers 11. The insulating layers (11, 21, 31) in the respective build-up parts may contain the same insulating resin or mutually different insulating resins. The insulating layers (21, 31) may each contain a core material (reinforcing material) formed of a glass fiber or an aramid fiber. In the illustrated example, the insulating layers 31 of the third build-up part 30 each contain, for example, a core material (31b) formed of a glass fiber. The insulating layers (21, 31) may each further contain an inorganic filler (not illustrated in the drawings) formed of fine particles of silica (SiO₂), alumina, mullite, or the like.

Similar to the conductor layers 12 and the via conductors 13, the conductor layers 22 of the second build-up part 20 and the conductor layer 32 of the third build-up part 30, as well as the via conductors (23, 33), can be formed using any metal such as copper or nickel. As illustrated in FIG. 1, similar to the via conductors 13 in the first build-up part 10, the via conductors 23 included in the second build-up part 20 and the via conductors 33 included in the third build-up part 30 are formed to each have a tapered shape that is reduced in diameter from the second surface (1B) side toward the first surface (1F) side of the wiring substrate 1.

As described above, the wirings included in the conductor layers 22 of the second build-up part 20 and the conductor layers 32 of the third build-up part 30 have larger pattern widths and inter-pattern distances than the wirings included in the conductor layers 12 of the first build-up part 10. The conductor layers 22 are each formed thicker than each of the conductor layers 12, and each have a thickness of, for example, about 10-15 μm or more. For example, the wirings included in the conductor layers 22 have a minimum wiring width of about 4-10 μm and a minimum inter-wiring distance of about 6-15 μm. In the second build-up part 20, the insulating layers 21 each have a thickness of, for example, about 20-30 μm.

In the wiring substrate 1 of the example illustrated in FIG. 1, the thickness of each of the insulating layers 31 of the third build-up part 30 is greater than the thickness of each of the insulating layers 11 of the first build-up part 10 and greater than the thickness of each of the insulating layers 21 of the second build-up part 20. The thickness of each of the conductor layers 32 in the third build-up part 30 is greater than the thickness of each of the conductor layers 12 in the first build-up part 10 and greater than the thickness of each of the conductor layers 22 in the second build-up part 20. For example, the thickness of each of the insulating layers 31 is about 100 μm or more and about 200 μm or less. Therefore, in the illustrated example, a total thickness of the insulating layers 31 in the third build-up part 30 (specifically, a shortest distance between the upper surface of the insulating layer 31 that forms the surface (30F) and the lower surface of the insulating layer 31 that forms the surface (30B)) can be 200 μm or more. Further, the thickness of each of the conductor layers 32 can be about 20 μm.

Similar to the conductor layers 12 and the via conductors 13, the conductor layers (22, 32) and the via conductors (23, 33) may be formed to each have a multilayer structure, and can each have a two-layer structure including a metal film layer (which can be, for example, a sputtering film layer or an electroless plating film layer) and a plating film layer (which can be, for example, an electrolytic plating film layer).

In the example of FIG. 1, the wiring substrate 1 further includes a solder resist layer 41 formed on the second surface (1B) that is formed by the surfaces of the insulating layer 31 and the conductor layer 32. The solder resist layer 41 is formed using, for example, a photosensitive polyimide resin or epoxy resin. Openings (41a) are formed in the solder resist layer 41, and conductor pads (32p) of the conductor layer 32 of the third build-up part 30 are exposed from the openings (41a).

The second surface (1B) of the wiring substrate 1 on the opposite side with respect to the first surface (1F) (which is the component mounting surface of the wiring substrate 1) can be a connection surface that is to be connected to an external element such as an external wiring substrate (for example, a motherboard of any electrical device) when the wiring substrate 1 itself is mounted on the external element. The conductor pads (32p) can be connected to any substrate, electrical component, mechanism component, or the like.

The wiring substrate 1 of the embodiment is preferably formed as a coreless wiring substrate that does not include a core layer. The second build-up part 20 is formed between the first build-up part 10 and the third build-up part 30. In the illustrated example, the first build-up part 10, the second build-up part 20, and the third build-up part 30 are continuously laminated. However, it is also possible that a build-up part including insulating layers and conductor layers is further interposed between the first build-up part 10 and the second build-up part 20, or between the second build-up part 20 and the third build-up part 30.

Next, with reference to FIGS. 2A-2M, a method for manufacturing the wiring substrate of the embodiment is described using a case where the wiring substrate 1 illustrated in FIG. 1 is manufactured as an example. Structural elements formed in the manufacturing method to be described below can be formed using the materials exemplified as the materials of the corresponding structural elements in the description of the wiring substrate 1 in FIG. 1, unless otherwise specified. In the following description about the manufacture of the wiring structure 1, a side closer to a support substrate (GS) is referred to as “lower” or a “lower side,” and a side farther from the support substrate (GS) is referred to as “upper” or an “upper side.” Therefore, of each of the elements of the wiring structure 1, a surface facing the support substrate (GS) is referred to as a “lower surface,” and a surface facing the opposite side with respect to the support substrate (GS) is also referred to as an “upper surface.”

The wiring substrate 1 can be formed by manufacturing the first build-up part 10 on the support substrate (GS), and manufacturing the second build-up part 20 on the first build-up part 10 and the third build-up part 30 on the second build-up part 20 (see FIG. 1).

In the following, among FIGS. 2A-2M to be referenced, in FIGS. 2A-2J, each conductor layer is depicted as two separate layers formed of a metal film layer and an electrolytic plating film layer, which are components of each conductor layer. However, in FIGS. 2K-2M, each conductor layer is depicted as a single layer, similar to that in FIG. 1.

First, as illustrated in FIG. 2A, for example, a support substrate (GS) having good surface flatness, such as a glass substrate, is prepared. On both sides of the support substrate (GS), a metal film layer 121 is formed via an adhesive layer (AL) containing, for example, an azobenzene-based polymer adhesive that can be attached or detached by irradiation with light. The metal film layer 121 is, for example, a metal film (preferably copper film) layer formed by electroless plating or sputtering or the like. It is also possible that the metal film layer 121 is formed of a relatively thin metal foil.

Next, as illustrated in FIG. 2B, a conductor layer 12 that has the multiple conductor pads (12p) and includes the metal film layer 121 and the plating film layer 122 is formed via the adhesive layer (AL) on the support substrate (GS).

In forming the conductor layer 12, for example, a plating resist is formed on the metal film layer 121, and openings are formed in the plating resist according to formation regions of patterns of the conductor pads (12p), for example, by photolithography. Next, the plating film layer 122 is formed in the openings by electrolytic plating using the metal film layer 121 as a seed layer. After the formation of the plating film layer 122, the plating resist is removed, and the metal film layer 121 exposed by the removal of the plating resist is etched and the state illustrated in FIG. 2B is formed.

Next, as illustrated in FIG. 2C, an insulating layer 11 covering the conductor layer 12 is formed. As the insulating layer 11, for example, an insulating resin such as an epoxy resin or a phenol resin can be used. A fluorine resin, a liquid crystal polymer (LCP), a fluoroethylene resin (PTFE), a polyester resin (PE), or a modified polyimide resin (MPI) also may be used. The insulating layer 11 is formed by thermocompression bonding these resins molded into a film-like shape. Next, the through holes (11a) are formed at formation positions of the via conductors 13 (see FIG. 1) in the insulating layer 11, for example, by irradiation with CO₂ laser, excimer laser, or the like. Laser is irradiated from an upper side of the insulating layer 11. The through holes (11a) can be formed such that a diameter of each of the through holes (11a) decreases from the upper side to the lower side in the drawing. The through holes (11a) can be formed such that the diameter of each of the through holes (11a) at the upper surface of the insulating layer 11 is about 10 μm.

Although not illustrated, the formation of the through holes (11a) by irradiation with laser such as CO₂ laser can be performed by irradiating laser while protecting the surface of the insulating layer 11 by covering the surface with a protective film such as a polyethylene terephthalate (PET) film. The through holes (11a) penetrating the protective film and the insulating layer 11 are formed. Further, after the through holes (11a) are formed, a desmear treatment may be performed to prevent a decrease in adhesion or an increase in a resistance component or the like during the formation of the conductor layer 12 due to a processing-deformed substance occurring at bottoms of the through holes (11a). The desmear treatment can preferably be a dry desmear treatment using a plasma gas. The desmear treatment may also be performed while protecting the surface of the insulating layer 11 in a state in which a protective film such as a polyethylene terephthalate (PET) film is formed on the surface of the insulating layer 11.

In FIG. 2C, and in FIGS. 2D-2M to be referenced below, the laminate formed on the surface on one side of the support substrate (GS) is illustrated, and illustration of the laminate that can be formed on the surface on the opposite side is omitted. However, on the surface on the opposite side, conductor layers and insulating layers may be formed in the same manner and number as those on the surface on the one side or in different manner and number from those on the surface on the one side, or it is also possible that such conductor layers and insulating layers are not formed.

Next, as illustrated in FIG. 2D, the metal film layer 121 is formed on inner walls of the through holes (11a) and on the surface of the insulating layer 11 by electroless plating, sputtering, or the like. When a protective film is provided on the surface of the insulating layer 11 during the formation of the through holes (11a) and/or during the desmear treatment, the protective film can be peeled off before the formation of the metal film layer 121.

Next, as illustrated in FIG. 2E, a plating resist (R1) having openings (R11) corresponding to the conductor patterns included in the conductor layer 12 (see FIG. 2H) is provided on the metal film layer 121.

Next, as illustrated in FIG. 2F, the electrolytic plating film layer 122 is formed in the openings (R11) of the plating resist (R1) by electrolytic plating using the metal film layer 121 as a power feeding layer.

Next, as illustrated in FIG. 2G, after the plating resist (R1) is removed, a portion of the metal film layer 121 that is not covered by the electrolytic plating film layer 122 is removed by etching or the like. As a result, the conductor layer 12 that has the wirings (FW) and has a two-layer structure including the metal film layer 121 and the electrolytic plating film layer 122 is formed. Further, the via conductors 13 are formed by completely filling the through holes (11a) with the conductor forming the electrolytic plating film layer 122. For example, the conductor layer 21 can be formed to have a thickness of about 7 μm or less.

Next, as illustrated in FIG. 2H, using methods similar to the methods for forming the insulating layer 11, the conductor layer 12 and the via conductors 13 described above, a desired number of insulating layers 11 and conductor layers 12, as well as via conductors 13 penetrating the respective insulating layers 11, are formed.

Next, as illustrated in FIG. 2I, an outermost insulating layer 11 among the insulating layers 11 of the first build-up part 10 (see FIG. 2J) is formed on an upper side of the conductor layer 12. After that, the through holes (11a) for forming the via conductors 13 are formed by laser processing in the insulating layer 11 at positions corresponding to formation locations of the via conductors 13 (see FIG. 1).

Next, as illustrated in FIG. 2J, at the same time as the via conductors 13 filling the through holes (11a) are formed, a conductor layer 22 is formed using any method for forming conductor patterns, such as a semi-additive method. The formation of the first build-up part 10 including the multiple first insulating layers 11, the multiple first conductor layers 12, and the first via conductors 13, as well as the formation of the second conductor layer 22 that forms the surface (20F) (see FIG. 1) of the second build-up part 20, are completed.

Next, as illustrated in FIG. 2K, using methods similar to the methods for forming the uppermost insulating layer 11 in the first build-up part 10, the via conductors 13, and the conductor layer 22, desired multiple insulating layers 21 and conductor layers 22, as well as via conductors 23 filling the through holes (21a) penetrating the respective insulating layers 21, are formed. The through holes (21a) are formed such that a diameter of each of the through holes (21a) at the upper surface of the insulating layer 21 is at least greater than the diameter of each of the through holes (11a) at the upper surface of the insulating layer 11. The through holes (21a) can be formed such that the diameter of each of the through holes (21a) at the upper surface of the insulating layer 21 is about 50 μm. On the formed uppermost insulating layer 21, a conductor layer 32 is formed at the same time as the via conductors 23 filling the through holes (21a) are formed. The formation of the second build-up part 20 on the first build-up part 10, as well as the formation of the conductor layer 32 that forms the surface (30F) of the third build-up part 30 (see FIG. 1), are completed.

Next, as illustrated in FIG. 2L, on the outermost insulating layer 21 of the second build-up part 20 and on the conductor layer 32, insulating layers 31, conductor layers 32, and via conductors 33 filling through holes (31a) penetrating the insulating layers 31 are formed. The insulating layers 31, the conductor layers 32, and the via conductors 33 are formed using methods similar to the method for forming the insulating layer 21, the conductor layer 32 and the via conductors 23. As an insulating resin forming the insulating layers 31, a prepreg containing an insulating resin such as an epoxy resin or a BT resin impregnated in a reinforcing material (core material) (31b) formed of a glass fiber can be used. As illustrated, the third build-up part 30 including two insulating layers 31 and three conductor layers 32 can be formed. For example, the insulating layers 31 can be formed to each have a thickness of about 100 μm or more and 200 μm or less, and have a total thickness (in the illustrated example, a total thickness of the two insulating layers 31) of 200 μm or more. The through holes (31a) are formed such that a diameter of each of the through holes (31a) at the upper surface of the insulating layer 31 is at least greater than the diameter of each of the through holes (21a) at the upper surface of the insulating layer 21. The through holes (31a) can be formed such that the diameter of each of the through holes (31a) at the upper surface of the insulating layer 31 is about 100 μm.

Next, the solder resist layer 41 is formed by forming a photosensitive epoxy resin or polyimide resin layer on the surfaces of the insulating layer 31 and the conductor layer 32. Then, using a photolithography technology, the openings (41a) that respectively define the conductor pads (32p) are formed.

Next, as illustrated in FIG. 2M, the support substrate (GS) is removed. The lower surfaces of the conductor pads (12p) and the lower surface of the insulating layer 11 are exposed. In removing the support substrate (GS), the adhesive layer (AL) is irradiated with, for example, laser and is softened, and then the support substrate (GS) is peeled off from the conductor pads (12p) and the insulating layer 11. The adhesive layer (AL) that can remain on the surfaces of the conductor pads (12p) and the insulating layer 11 can be removed by washing. The wiring substrate 1 illustrated in FIG. 1 is completed.

The wiring substrate of the embodiment is not limited to those having the structures illustrated in the drawings and those having the structures, shapes, and materials exemplified herein. The build-up parts included in the wiring substrate of the embodiment can each have any number of insulating layers and conductor layers. For example, it is also possible that the insulating layers 31 of the third build-up part 30 do not each contain a core material (31b). It is also possible that the thickness of each of the insulating layers 31 of the third build-up part 30 is smaller than the thickness of each of the insulating layers 21 of the second build-up part. It is also possible that the thickness of each of the conductor layers 32 of the third build-up part 30 is smaller than the thickness of each of the conductor layers 22 of the second build-up part.

International Publication No. 2010/010910 describes a coreless substrate having a first surface and a second surface on the opposite side with respect to the first surface. The coreless substrate includes multiple (three) insulating layers. In the three insulating layers, vias are formed that each penetrate an insulating layer and electrically connect wirings provided above and below the insulating layer. Dimensions (diameters and heights) of the vias penetrating different insulating layers among the three insulating layers are different. The dimensions of the vias increase with each insulating layer from the vias formed in the insulating layer on the first surface side to the vias formed in the insulating layer on the second surface side.

In the coreless substrate described in International Publication No. 2010/010910, the dimensions of the vias formed are different for each insulating layer. It is thought that structures of circuits that can be formed through vias of the same dimensions may be relatively limited.

A wiring substrate according to an embodiment of the present invention has a first surface and a second surface on the opposite side with respect to the first surface, and includes: a first build-up part that includes alternately laminated first conductor layers and first insulating layers, and first via conductors penetrating the first insulating layers, and has the first surface; a third build-up part that includes alternately laminated third conductor layers and third insulating layers, and third via conductors penetrating the third insulating layers, and has the second surface; and a second build-up part that is formed between the first build-up part and the third build-up part, and includes alternately laminated second conductor layers and second insulating layers, and second via conductors penetrating the second insulating layers. A diameter of each of the first via conductors is smaller than a diameter of each of the second via conductors. The diameter of each of the second via conductors is smaller than a diameter of each of the third via conductors. The second build-up part includes the multiple second insulating layers and the multiple second conductor layers.

According to an embodiment of the present invention, a high-quality wiring substrate can be provided that has a relatively stable characteristic impedance and can accommodate a wiring circuit with a relatively complex structure by utilizing via conductors of similar dimensions (diameters).

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a first build-up part comprising a first conductor layer, a first insulating layer, and a plurality of first via conductors penetrating through the first insulating layer;
a second build-up part comprising a plurality of second conductor layers, a plurality of second insulating layers, and a plurality of second via conductors penetrating though the second insulating layers;
a third build-up part comprising a third conductor layer, a third insulating layer, and a plurality of third via conductors penetrating through the third insulating layer such that the second built-up part is formed between the first built-up part and the third build-up part,
wherein the first, second and third build-up parts are formed such that a diameter of each of the first via conductors is smaller than a diameter of each of the second via conductors and that the diameter of each of the second via conductors is smaller than a diameter of each of the third via conductors.

2. The wiring substrate according to claim 1, wherein the first build-up part is formed such that the first insulating layer is formed in a plurality, the first conductor layer is formed in a plurality, and the plurality of first insulating layers and the plurality of first conductor layers are laminated alternately.

3. The wiring substrate according to claim 2, wherein the first and second build-up parts are formed such that a number of the second insulating layers is greater than a number of the first insulating layers, and a number of the second conductor layers is greater than a number of the first conductor layers.

4. The wiring substrate according to claim 1, wherein the third build-up part is formed such that the third insulating layer is formed in a plurality, the third conductor layer is formed in a plurality, and the plurality of third insulating layers and the plurality of third conductor layers are laminated alternately.

5. The wiring substrate according to claim 4, wherein the third build-up part is formed such a total thickness of the third insulating layers in the third build-up part is 200 μm or more.

6. The wiring substrate according to claim 1, wherein the plurality of second conductor layers in the second build-up part includes a plurality of wirings, and the first conductor layer in the first build-up part includes a plurality of first wirings formed such that wiring widths of the first wirings are smaller than a minimum wiring width of the wirings in the second conductor layers and that inter-wiring distances of the first wirings are smaller than a minimum inter-wiring distance of the wirings in the second conductor layers.

7. The wiring substrate according to claim 6, wherein the first build-up part is formed such that aspect ratios of the first wirings are in a range of 2.0 to 4.0, the wiring widths of the first wirings are 3 μm or less, and the inter-wiring distances of the first wirings are 3 μm or less.

8. The wiring substrate according to claim 6, wherein the first build-up part is formed such that the first build-up part includes a plurality of conductor pads formed in a plurality of component mounting regions and connected via the wirings in the first conductor layer.

9. The wiring substrate according to claim 1, wherein the first build-up part is formed such that a diameter of each of the first via conductors at an upper surface of a lower conductor layer to which each of the first via conductors is connected is about 10 μm.

10. The wiring substrate according to claim 1, wherein the third build-up part is formed such that the third insulating layer includes a core material.

11. The wiring substrate according to claim 10, wherein the core material includes a glass fiber.

12. The wiring substrate according to claim 1, wherein the first, second and third build-up parts are formed such that the first via conductors, the second via conductors, and the third via conductors have shapes that is reduced in diameter in a direction from the third build-up part toward the first build-up part.

13. The wiring substrate according to claim 1, wherein the first build-up part is formed such that the first conductor layer and first via conductors include a first seed layer comprising a sputtering film and a first plating film layer formed on the first seed layer, and the second build-up part is formed such that the second conductor layers and second via conductors include a plurality of second seed layers each comprising an electroless plating film and a plurality of second plating film layers formed on the second seed layer, respectively.

14. The wiring substrate according to claim 1, wherein the first and second build-up parts are formed such that an outermost second conductor layer of the second conductor layers on a first build-up part side and the first via conductors have integral conductor structures.

15. The wiring substrate according to claim 2, wherein the third build-up part is formed such that the third insulating layer is formed in a plurality, the third conductor layer is formed in a plurality, and the plurality of third insulating layers and the plurality of third conductor layers are laminated alternately.

16. The wiring substrate according to claim 15, wherein the third build-up part is formed such a total thickness of the third insulating layers in the third build-up part is 200 μm or more.

17. The wiring substrate according to claim 2, wherein the plurality of second conductor layers in the second build-up part includes a plurality of wirings, and the plurality of first conductor layers in the first build-up part includes a plurality of first wirings formed such that wiring widths of the first wirings are smaller than a minimum wiring width of the wirings in the second conductor layers and that inter-wiring distances of the first wirings are smaller than a minimum inter-wiring distance of the wirings in the second conductor layers.

18. The wiring substrate according to claim 17, wherein the first build-up part is formed such that aspect ratios of the first wirings are in a range of 2.0 to 4.0, the wiring widths of the first wirings are 3 μm or less, and the inter-wiring distances of the first wirings are 3 μm or less.

19. The wiring substrate according to claim 17, wherein the first build-up part is formed such that the first build-up part includes a plurality of conductor pads formed in a plurality of component mounting regions and connected via wirings in an outermost one of the first conductor layers.

20. The wiring substrate according to claim 3, wherein the third build-up part is formed such that the third insulating layer is formed in a plurality, the third conductor layer is formed in a plurality, and the plurality of third insulating layers and the plurality of third conductor layers are laminated alternately.
